(19) United States
(12) Patent Application Publication
(10) Pub. No.: US 2009/0250785 A1
(43) Pub. Date: Oct. 8, 2009

(54) METHODS OF FORMING A SHALLOW BASE REGION OF A BIPOLAR TRANSISTOR

(76) Inventors: Thomas Joseph Krutsick, Fleetwood, PA (US); Christopher J. Speyer, Spicewood, TX (US)

Correspondence Address: WILLIAMS, MORGAN & AMERSON, 10333 RICHMOND, SUITE 1100, HOUSTON, TX, 77042, US

(21) Appl. No.: 12/061,231

(22) Filed: Apr. 2, 2008

(51) Int. Cl. H01L 29/732; H01L 21/331

(52) U.S. Cl. 257/526; 438/311; 257/E29.183; 257/E21.375

(57) ABSTRACT

The disclosed subject matter provides a method of forming a bipolar transistor. The method includes depositing a first insulating layer over a first layer of material that is doped with a dopant of a first type. The first layer is formed over a substrate. The method also includes modifying a thickness of the first oxide layer based on a target dopant profile and implanting a dopant of the first type in the first layer. The dopant is implanted at an energy selected based on the modified thickness of the first insulating layer and the target dopant profile.

### BACKGROUND

1. Field of the Invention

This invention relates generally to bipolar transistors and, more particularly, to forming shallow base regions of bipolar transistors.

2. Description of the Related Art

Bipolar transistors include an emitter region, a base region, and a collector region that are alternately doped with either n-type or p-type material. For example, an n-p-n bipolar transistor includes an emitter region that is doped with n-type material, a base region that is doped with p-type material, and a collector region that is doped with n-type material. For another example, a p-n-p bipolar transistor includes an emitter region that is doped with p-type material, a base region that is doped with n-type material, and a collector region that is doped with p-type material. The structure and operating parameters of a bipolar transistor are therefore determined, at least in part, by the dopant profiles that result from the specific processes that are used to dope the emitter, base, and/or collector regions.

FIGS. 1A, 1B, 1C, and 1D conceptually illustrate a conventional technique for forming an n-p-n bipolar transistor. Initially, as shown in FIG. 1A, an SOI substrate 100 is used as the starting material for the present invention. As depicted in FIG. 1A, the SOI substrate 100 is comprised of a bulk substrate 100a, a buried insulation layer 100b and an active layer 100c. Typically the bulk silicon 100a is comprised of silicon, the buried insulation layer 100b is comprised of silicon dioxide (a so-called “BOX” layer), and the active layer 100c is comprised of silicon (doped or undoped). Such SOI structures may be readily obtained from a variety of commercially known sources. Typically, the buried insulation layer 100b will be relatively thick, e.g., on the order of approximately 0.5-2 microns, and the active layer 100c may have an initial thickness of approximately 2 microns.

Thereafter, as indicated in FIG. 1A, a doped layer of silicon 105 is formed above the active layer 100c. The layer of silicon 105 is doped with an N-type dopant material, e.g., phosphorous, arsenic, such that it has a resistivity of approximately 2-15 ohm-cm which corresponds to a dopant concentration of approximately 2×10¹⁴ to 2.5×10¹⁵ ions/cm³. The layer of silicon 105 is a layer of epitaxial silicon that is deposited in an epi reactor. In this situation, the layer of epitaxial silicon 105 may be doped by introducing dopant materials into an epi reactor during the process used to form the layer 105. However, the dopant material may also be introduced into the layer of silicon 105 by performing an ion implant process after the layer of silicon 105 is formed. Note that the distribution of dopant atoms within the layer of silicon 105 may not be uniform throughout its depth.

For purposes of explanation only, the drawings depict an interface between the active layer 100c and the layer of silicon 105. In practice, the distinction between these two layers may be very difficult to define. Nevertheless, the distinct layers are shown for purposes of explanation only. The layer of silicon 105 is relatively thick. In one illustrative embodiment, the layer of silicon 105 has a thickness that ranges from approximately 1-30 microns, depending on the particular application. Thereafter, an oxide layer 110 (such as silicon dioxide) is formed above the layer of silicon 105 by performing, for example, a thermal oxidation. At this point in the processing, a p-n-p bipolar transistor could be formed by performing a dopant implantation process (indicated by the arrows 115) could be performed to implant dopant species in the silicon layer 105. For example, the dopant implantation process 115 may be used to implant a p-type dopant such as boron into the silicon layer 105 to form a doped region 120. However, FIG. 1 depicts formation of an n-p-n bipolar transistor and so this step is not performed.

Referring now to FIG. 1C, a thermal oxidation process can be used to grow selected portions of the silicon dioxide layer 110. In the illustrated embodiment, the thermal oxidation process is used to grow the portions 125(1-2) and a masking layer (not shown) is used to prevent the region between these portions from growing. Thermal oxidation and the consequent growth of the portions 125 consume a portion of the doped region 120.

Referring now to FIG. 1D, a base region 130 for the n-p-n bipolar transistor may be formed by implanting a p-type dopant in a portion of the silicon layer 105, as indicated by the arrows 135. The dopant concentration in the base region 130 is typically approximately 10¹⁶-10¹⁸ ions/cm³. The dopant is typically implanted at energy of more than about 50 keV for boron (a p-type dopant) and, in the alternate case of a p-n-p bipolar transistor 100 kev for the n-type dopants such as phosphorous. These relatively high implant energies typically result in high implant straggle and cause the implanted dopant species to have a relatively shallow peak that extends deeply into the silicon layer 105. For example, the depth of the base region 130 may be much larger than a few thousand angstroms. Implanting the dopant concentration at these high energies may also result in channeling effects in the base region 130. For example, a small percentage of the dopant atoms may penetrate very deeply into the layer 105 before colliding with the silicon lattice.

The slope of the tail of the dopant concentration in the base region 130 may be increased by decreasing the energy used for the implantation process 135. However, the dopant species that are implanted at lower energy are subject to surface issues, e.g., native oxide variation may affect the implant profile. Consequently, these low energy techniques require substantial surface preparation and/or other non-standard implantation techniques, which dramatically increase the complexity and cost of the implantation process. Using materials such as BF2 may also help to alleviate these problems. However, the use of BF2 may result in contamination and/or other problems from the fluorine component.

The present invention is directed to addressing the effects of one or more of the problems set forth above.

### SUMMARY OF THE DISCLOSED SUBJECT MATTER

The following presents a simplified summary of the disclosed subject matter in order to provide a basic understanding of some aspects of the disclosed subject matter. This summary is not an exhaustive overview of the disclosed subject matter. It is not intended to identify key or critical elements of the disclosed subject matter or to delineate the scope of the disclosed subject matter. Its sole purpose is to present some concepts in a simplified form as a prelude to the more detailed description that is discussed later.

In one embodiment of the disclosed subject matter, a method is provided for forming a bipolar transistor. The method includes forming a first insulating layer over a first layer of material that is doped with a dopant of a first type. The first layer is formed over a substrate. The method also includes modifying a thickness of the first insulating layer based on a target dopant profile and implanting a dopant of the first type in the first layer. The dopant is implanted at an energy selected based on the modified thickness of the first insulating layer and the target dopant profile.

In another embodiment of the disclosed subject matter, a bipolar transistor is provided. The bipolar transistor includes a substrate, a first layer of material formed over the substrate, and a first oxide layer. The first layer includes a first portion doped with a dopant of a first type and a second portion doped with a dopant of a second type that is opposite the first type. The second portion is doped by modifying a thickness of the first insulating layer based on a target dopant profile and implanting a dopant of the first type in the first layer. The dopant is implanted at an energy selected based on the thickness of the first insulating layer and the target dopant profile.

### BRIEF DESCRIPTION OF THE DRAWINGS

The disclosed subject matter may be understood by reference to the following description taken in conjunction with the accompanying drawings, in which like reference numerals identify like elements, and in which:

FIGS. 1A, 1B, 1C, and 1D conceptually illustrate aspects of conventional techniques for forming a bipolar transistor;

FIGS. 2A, 2B, 2C, and 2D conceptually illustrate a first exemplary embodiment of a technique for forming an n-p-n bipolar transistor, in accordance with the disclosed subject matter;

FIGS. 3A and 3B conceptually illustrate a second exemplary embodiment of a technique for forming a base of an n-p-n bipolar transistor, in accordance with the disclosed subject matter;

FIG. 4 conceptually illustrates exemplary embodiments of dopant profiles such as may be formed using the first and second exemplary embodiments shown in FIGS. 2 and 3, in accordance with the disclosed subject matter;

FIG. 5 conceptually illustrates an exemplary embodiment of a dopant profile formed in accordance with the disclosed subject matter; and

FIG. 6 conceptually illustrates a comparison of a conventional dopant profile and a dopant profile that is formed in accordance with the disclosed subject matter.

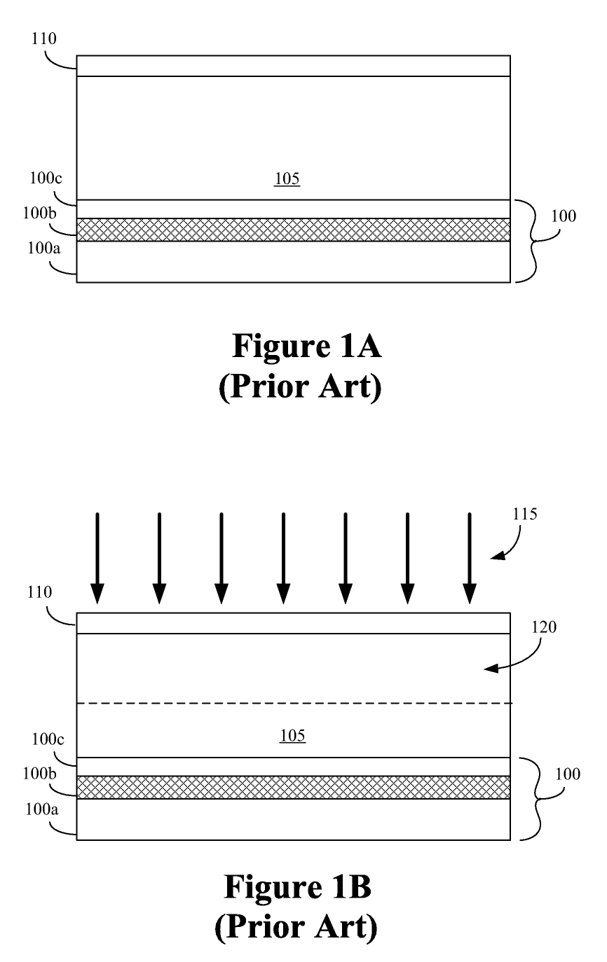

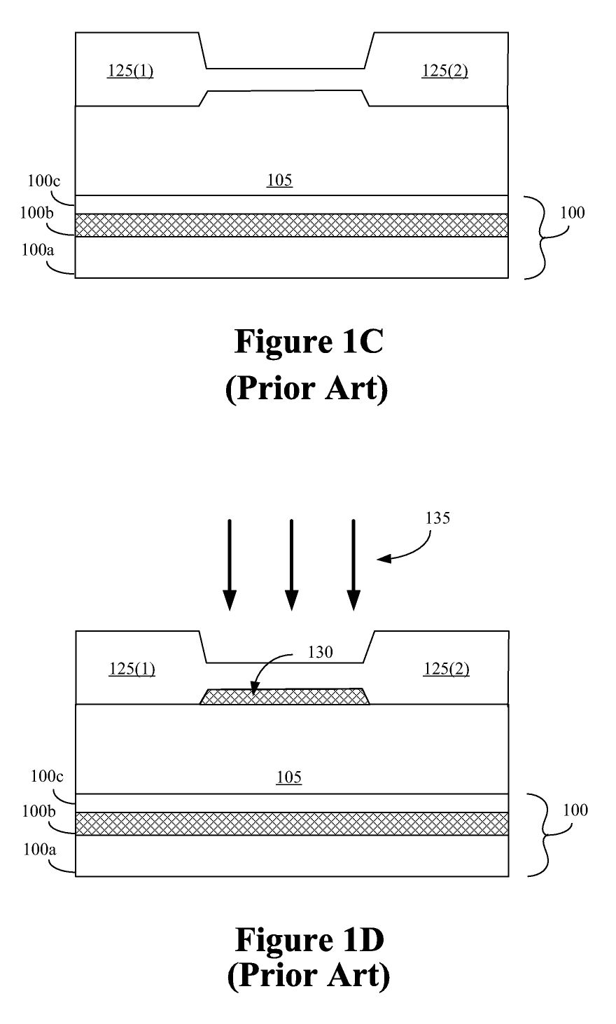

While the disclosed subject matter is susceptible to various modifications and alternative forms, specific embodiments thereof have been shown by way of example in the drawings and are herein described in detail. It should be understood, however, that the description herein of specific embodiments is not intended to limit the disclosed subject matter to the particular forms disclosed, but on the contrary, the intention is to cover all modifications, equivalents, and alternatives falling within the scope of the disclosed subject matter as defined by the appended claims.

### DETAILED DESCRIPTION OF SPECIFIC EMBODIMENTS

Illustrative embodiments of the disclosed subject matter are described below. In the interest of clarity, not all features of an actual implementation are described in this specification. It will of course be appreciated that in the development of any such actual embodiment, numerous implementation-specific decisions should be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The disclosed subject matter will now be described with reference to the attached figures. Various structures, systems and devices are schematically depicted in the drawings for purposes of explanation only and so as to not obscure the disclosed subject matter with details that are well known to those skilled in the art. Nevertheless, the attached drawings are included to describe and explain illustrative examples of the disclosed subject matter. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

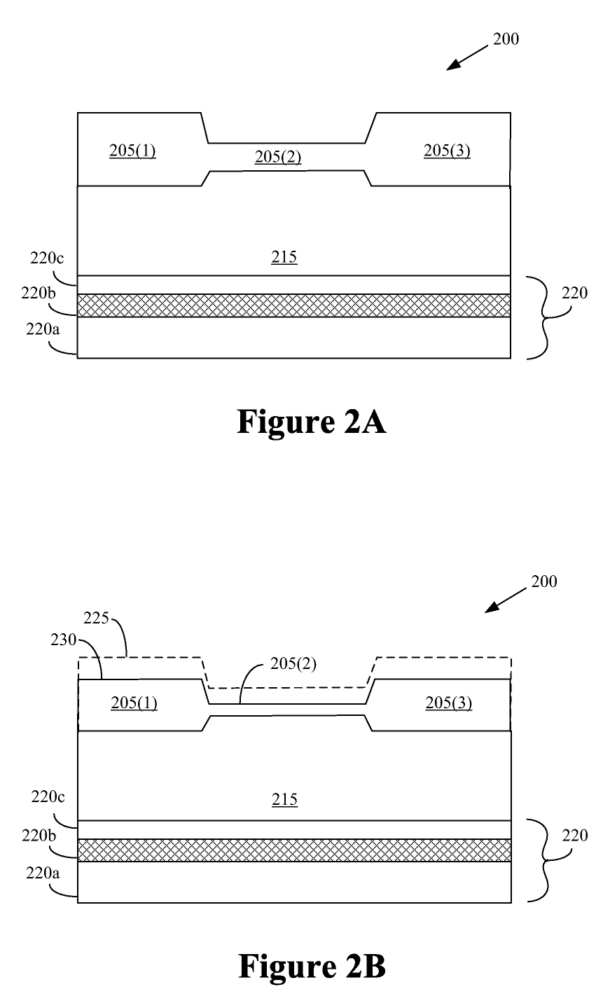

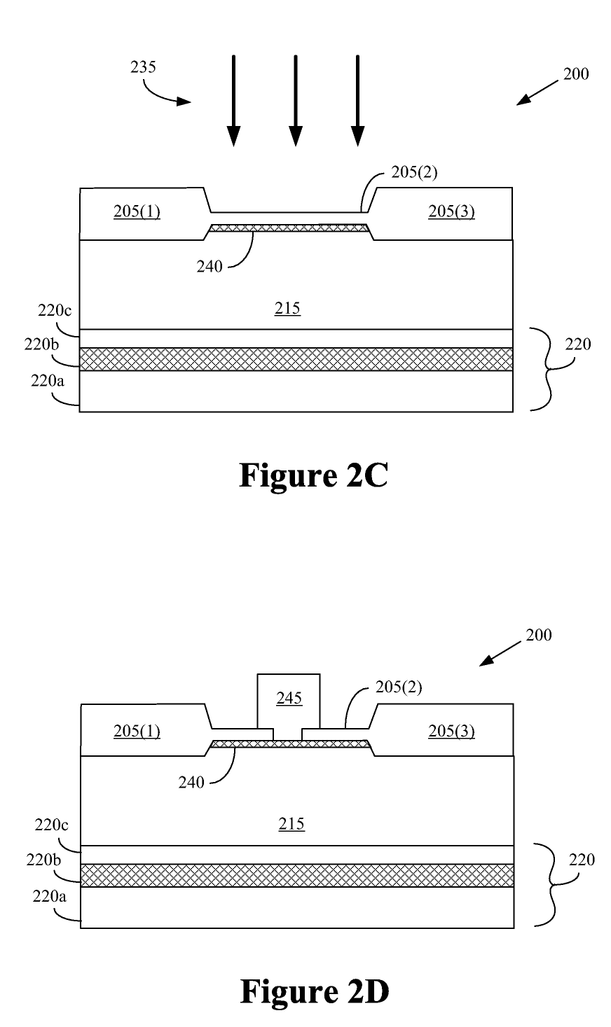

FIGS. 2A, 2B, 2C, and 2D conceptually illustrate a first exemplary embodiment of a technique for forming an n-p-n bipolar transistor 200. However, persons of ordinary skill in the art having benefit of the present disclosure should appreciate that the techniques described herein are equally applicable to p-n-p bipolar transistors. FIG. 2A depicts the bipolar transistor 200 at an intermediate stage in the fabrication process. At the stage depicted in FIG. 2A, the bipolar transistor includes an insulating layer 205. In the illustrated embodiment, the insulating layer 205 is a pad oxide layer 205, although the transistors described herein may utilize other types of insulators. In the illustrated embodiment, a thermal oxidation process has been used to grow portions 205(1, 3) of the pad oxide layer 205 and a masking process is used to prevent the region 205(2) between the portions 205(1, 3) from growing. In the illustrated embodiment, the regions 205(1, 3) are grown to a thickness of approximately 0.25-1 microns and the region 205(2) has a thickness of approximately 300-1400 angstroms. Techniques for depositing the pad oxide layer 205 and then selectively growing portions of the pad oxide layer 205 are known in the art and in the interest of clarity will not be discussed further herein.

The pad oxide layer 205 is formed over a portion of a silicon layer 215, although persons of ordinary skill in the art having benefit of the present disclosure should appreciate that the layer 245 may alternatively be formed of polysilicon. In one embodiment, the layer of silicon 215 may be doped with an N-type dopant material, e.g., phosphorous, arsenic, such that it has a resistivity of approximately 2.5 ohm-cm which corresponds to a dopant concentration of approximately 2×10¹⁵ ions/cm³. In one particular embodiment, the layer of silicon 215 is a layer of epitaxial silicon that is deposited in an epi reactor. In this situation, the layer of epitaxial silicon 215 may be doped by introducing dopant materials into an epi reactor during the process used to form the layer 215. However, the dopant material may also be introduced into the layer of silicon 215 by performing an ion implant process after the layer of silicon 215 is formed. Note that the distribution of dopant atoms within the layer of silicon 215 may not be uniform throughout its depth. In cases where the bipolar transistor 200 is a p-n-p type bipolar transistor, a dopant implantation process may be used to implant a p-type dopant such as boron into the silicon layer 215 to form a doped region referred to as a p-well. The dopant concentration in the p-well may be approximately 1×10¹⁶ ions/cm³. However, the illustrated embodiment of the bipolar transistor 200 is an n-p-n type bipolar transistor and so this process is not performed in the illustrated embodiment.

The silicon layer 215 is formed on a substrate, such as a silicon substrate or a silicon-on-insulator (SOI) substrate. In the embodiment shown in FIG. 2, the silicon layer 215 is deposited on an SOI substrate 220 that is comprised of a bulk substrate 220a, a buried insulation layer 220b and an active layer 220c. The bulk silicon 220a is comprised of silicon, the buried insulation layer 220b is comprised of silicon dioxide (a so-called “BOX” layer), and the active layer 220c is comprised of silicon (doped or undoped). Such SOI structures may be readily obtained from a variety of commercially known sources. Typically, the buried insulation layer 220b will be relatively thick, e.g., on the order of approximately 0.5-2 microns, and the active layer 220c may have an initial thickness of approximately 2 microns.

Referring now to FIG. 2B, a base region for the n-p-n bipolar transistor 200 may be formed by implanting a p-type dopant in a portion of the silicon layer 215. The operating properties of the base region and the bipolar transistor 200 are determined, at least in part, by the profile of the dopant species that is implanted in the base region. For example, the characteristic properties of the base region may be determined by the straggle of the dopant profile that characterizes the width or steepness of the dopant profile, the depth of the peak of the dopant profile in the silicon layer 215, and the like. Persons of ordinary skill in the art having benefit of the present disclosure will appreciate that the term “straggle” refers to a statistical measure of the width or steepness of the dopant profile. If the dopant profile is normally distributed, then the straggle is equal to the standard deviation of the dopant profile. A target dopant profile (which may be represented by parameters such as the straggle, the standard deviation, and/or the peak depth) may be selected based upon the desired properties of the base region. The actual dopant profile that is formed in the silicon layer 215 can be controlled by varying the energy used to implant the dopant species and the thickness of the pad oxide layer 205 through which the dopant species is implanted into the silicon layer 215.

In the first exemplary embodiment, the thickness of the pad oxide layer 205 is modified by etching back portions of the pad oxide layer 205 from the original thickness (as indicated by the dotted line 225) to a reduced thickness (as indicated by the solid line 230). The etching process may be controlled so that the thickness of the pad oxide layer in the region 205(2) reaches a value that is determined based upon the target dopant profile. For example, the pad oxide layer 205 may be etched so that the thickness of the region 205(2) is approximately 400 Å.

FIG. 2C depicts the implantation, as indicated by the arrows 235, of ions into the base region 240. The energy of the implanted dopant species is selected based upon the target dopant profile and the thickness of the pad oxide layer 205. In the illustrated embodiment, the dopant species is implanted at a relatively low energy within the range 5-30 keV. For example, the dopant species (such as boron) may be implanted at an energy of about 20 keV when the thickness of the region 205(2) is approximately 400 Å. The resulting dopant concentration in the base region 240 is approximately 10¹⁶-10¹⁸ ions/cm³ for an implant dose of approximately 2×10¹³ ions/cm². Collisions in the pad oxide layer 205 may randomize the implanted dopant species, which may increase the steepness of the dopant profile and reduce the effects of channeling in the base region 240. For example, when the dopant species is implanted using an energy of about 15 keV through a thickness of approximately 400 Å, the target range of the dopant profile as approximately 500 Å and the standard deviation or straggle of the dopant profile is approximately 100 Å.

In FIG. 2D, an n-type emitter 245 has been formed over the pad oxide 205. The emitter 245 also contacts the base region 240 through a portion of the pad oxide 205. Techniques for forming the emitter 245 are known in the art and in the interest of clarity will not be discussed further herein. Persons of ordinary skill in the art having benefit of the present disclosure should also appreciate that additional regions such as collector regions, sinkers, and the like may also be formed as part of the bipolar transistor 200.

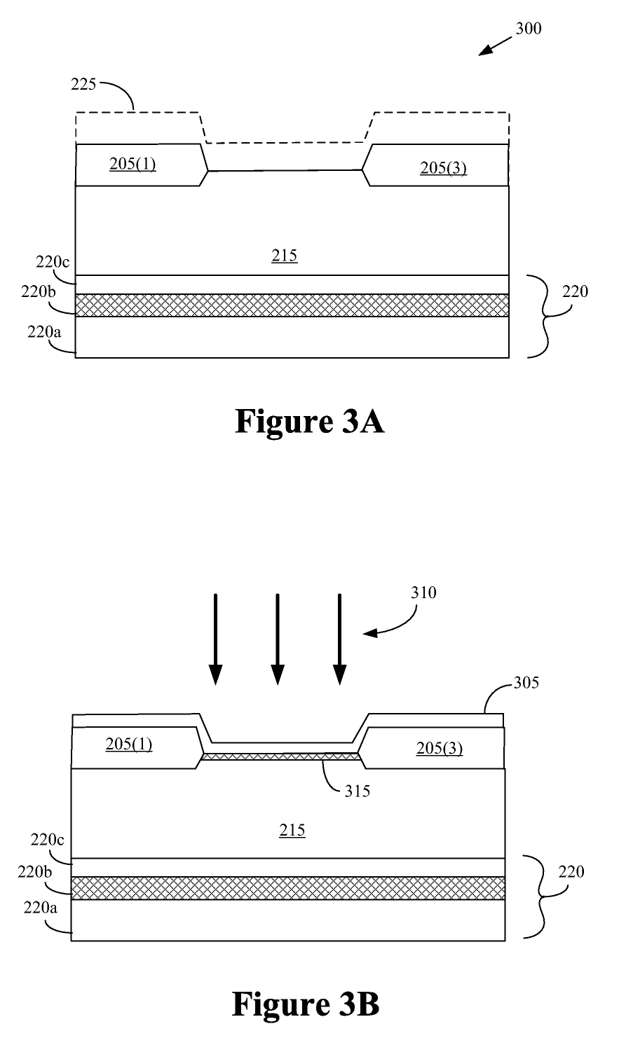

FIGS. 3A and 3B conceptually illustrate a second exemplary embodiment of a technique for forming an n-p-n bipolar transistor 300. However, persons of ordinary skill in the art having benefit of the present disclosure should appreciate that these techniques may also be applied to the formation of a p-n-p bipolar transistor. In the second exemplary embodiment, the thickness of the pad oxide layer 205 is modified by etching back portions of the pad oxide layer 205 from the original thickness (as indicated by the dotted line 225) until the region 205(2) is substantially completely removed. For example, the pad oxide layer 205 may be etched until a portion of the doped region 210 of the silicon layer 215 is exposed in the region beneath the region 205(2).

In FIG. 3B, an additional oxide layer 305 is deposited over the regions 205(1, 3) and the exposed portion of the doped layer 210. The deposition process may be controlled so that the thickness of the additional oxide layer 305 over the exposed portion of the doped layer 210 reaches a value that is determined based upon the target dopant profile. For example, the thickness of the additional oxide layer 305 over the exposed portion of the doped layer 210 may be approximately 400 Å. The dopant species may then be implanted as indicated by the arrows 310, of ions into the base region 315. The energy of the implanted dopant species is selected based upon the target dopant profile and the thickness of the additional oxide layer 305. In the illustrated embodiment, the dopant species is implanted at a relatively low energy within the range 5-30 keV. For example, the dopant species may be implanted at an energy of about 20 keV when the thickness of the additional oxide layer 305 is approximately 400 Å.

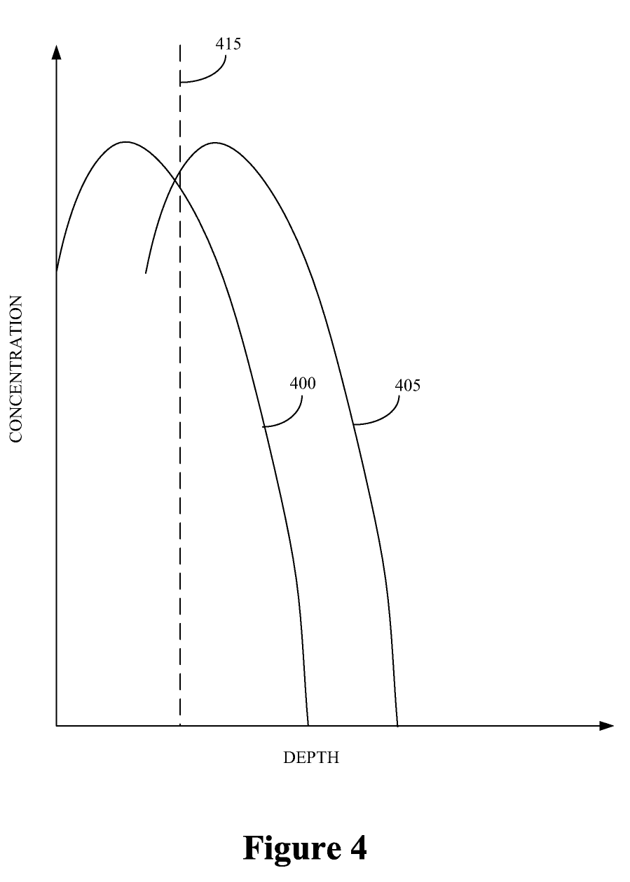

FIG. 4 conceptually illustrates exemplary embodiments of dopant profiles 400, 405 such as may be formed using the techniques shown in FIGS. 2 and 3. The horizontal axis indicates depth into the layers in arbitrary units and the vertical axis indicates the dopant concentration in arbitrary units. The vertical dashed line 415 indicates the boundary between the pad oxide layer and the silicon layer. The dopant profile 400 is formed by selecting the thickness of the pad oxide layer and the energy of the implanted dopants species such that the peak of the dopant profile 400 lies within the pad oxide layer. Consequently, the dopant profile 400 in the silicon layer includes the tail of the profile and so the dopant profile 400 and the silicon layer is shallow and steep. The dopant profile 405 is formed by selecting the thickness of the pad oxide layer and the energy of the implanted dopants species such that the peak of the dopant profile 405 lies within the silicon layer. Consequently, the dopant profile 405 in the silicon layer includes the peak and the tail of the profile 405. The dopant profile 405 is relatively narrow and maintains the steep tail.

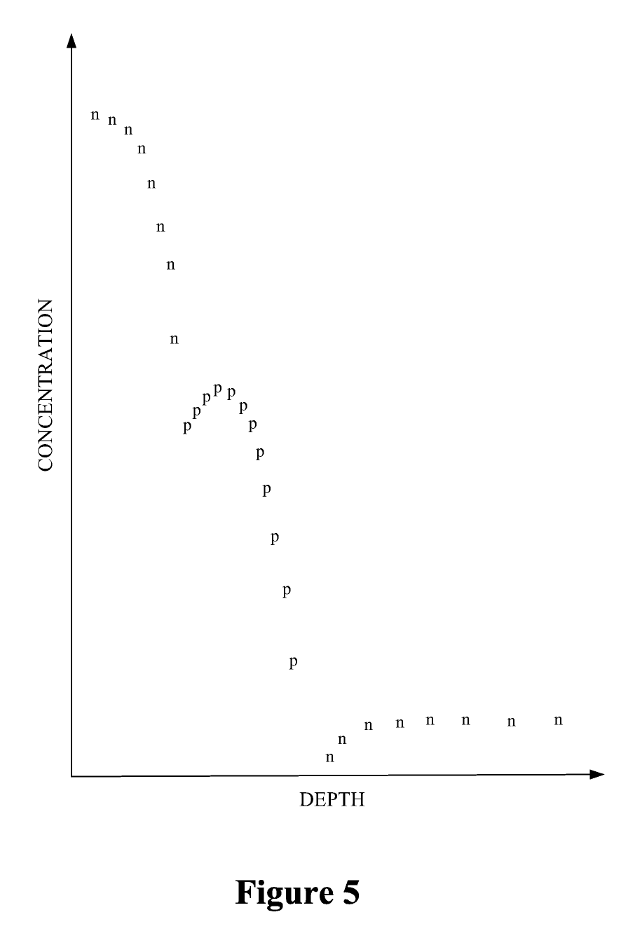

FIG. 5 conceptually illustrates an exemplary embodiment of a dopant profile for a bipolar transistor. The horizontal axis represents a depth in arbitrary units and the vertical axis represents the carrier concentration in arbitrary units. The type of the dopant species is indicated by the letter “n” for n-type dopants and “p” for p-type dopants. An emitter region is formed of n-type dopants at a concentration of about 10¹⁹ cm⁻³ in the region extending to about 0.5 microns. The base region, which may be formed using the techniques described herein, extends from about 0.5 microns to about 0.68 microns. The p-type dopant concentration in the base region ranges from about 3×10¹⁷ cm⁻³ to about 10¹⁶ cm⁻³. The tail of the base region is steep and does not exhibit any channeling effects. The collector region is formed with n-type dopants at depths below about 0.68 microns.

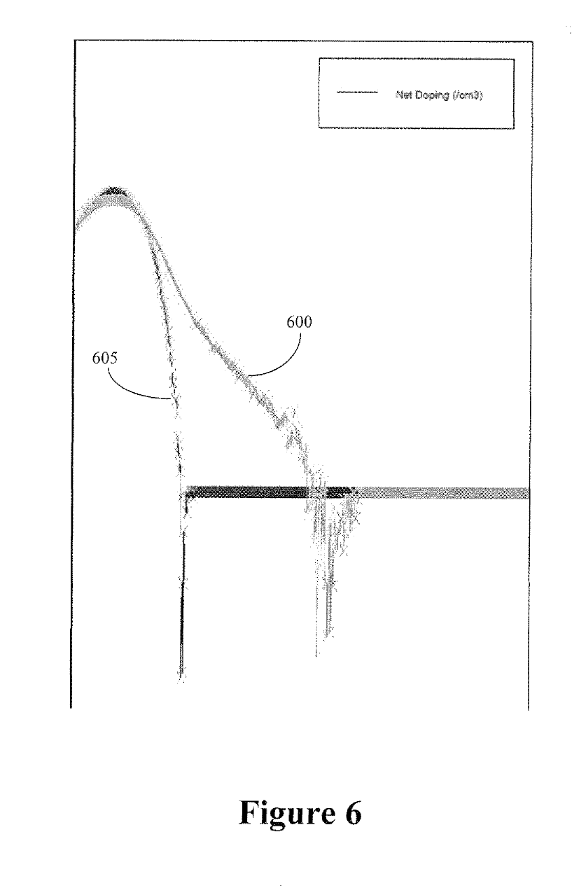

FIG. 6 conceptually illustrates a comparison of a conventional dopant profile 600 and a dopant profile 605 that is formed using embodiments of the techniques described herein. The conventional dope profile 600 has a relatively shallow tail and a relatively broad standard deviation, which may lead to channeling effects. In contrast, the dopant profile 605 that is formed according to embodiments of the techniques described herein has a relatively steep tail and a relatively narrow standard deviation, which may reduce channeling effects in the base region.

The particular embodiments disclosed above are illustrative only, as the disclosed subject matter may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope of the disclosed subject matter. Accordingly, the protection sought herein is as set forth in the claims below.

What is claimed:

1. A method of forming a bipolar transistor, comprising:
forming a first insulating layer over a first layer of material that is doped with a dopant of a first type, the first layer being formed over a substrate;
modifying a thickness of the first insulating layer based on a target dopant profile; and
implanting a dopant of the first type in the first layer, the dopant being implanted at an energy selected based on the modified thickness of the first insulating layer and the target dopant profile.

2. The method of claim 1, comprising:
depositing the first layer of silicon over the substrate, the substrate comprising at least one of a silicon substrate and a silicon-on-insulator substrate; and
doping the first layer of material with the dopant of the first type.

3. The method of claim 2, wherein depositing the first oxide layer comprises:
depositing the first oxide layer over the first layer of material; and
implanting a dopant of a second type through the first oxide layer and into a portion of the first layer of material that is adjacent to the first oxide layer, the second type of dopant being opposite the first type of dopant.

4. The method of claim 3, wherein forming the first insulating layer comprises forming a first oxide layer by thermal processes and growing a first portion of the first oxide layer such that a thickness of the first portion of the first oxide layer increases and a thickness of a second portion of the first oxide layer remains substantially the same.

5. The method of claim 4, wherein modifying the thickness of the first insulating layer comprises:
etching the first oxide layer such that the thickness of the second portion of the first oxide layer is approximately equal to a target thickness selected based upon the target dopant profile.

6. The method of claim and 4, wherein modifying the thickness of the first insulating layer comprises:
etching the first oxide layer such that the second portion of the first oxide layer is substantially removed to expose a portion of the first layer; and
depositing a second oxide layer over at least the exposed portion of the first layer, the second oxide layer having a thickness approximately equal to a target thickness selected based upon the target dopant profile.

7. The method of claims 5 or 6, comprising selecting the target thickness based on the target dopant profile.

8. The method of claim 7, wherein selecting the target thickness comprises selecting the target thickness based on at least one of a target straggle of the target dopant profile, a target standard deviation of the target dopant profile, or a target depth of a peak of the target dopant profile.

9. The method of claim 8, wherein implanting the dopant of the first type in the first oxide layer comprises implanting the dopant of the first type through the modified first oxide layer having a thickness of approximately 400 Å using an implant energy of approximately 5-30 keV for a p-type dopant.

10. The method of claim 8, wherein implanting the dopant of the first type in the first oxide layer comprises implanting the dopant of the first type through the modified first oxide layer having a thickness of approximately 400 Å using an implant energy of approximately 50-100 keV for an n-type dopant.

11. A bipolar transistor, comprising:
a substrate;
a first layer of material formed over the substrate, the first layer comprising a first portion doped with a dopant of a first type and a second portion doped with a dopant of a second type that is opposite the first type; and
a first insulating layer formed over the first layer, wherein the second portion is doped by:
modifying a thickness of the first insulating layer based on a target dopant profile; and
implanting a dopant of the first type in the first layer, the dopant being implanted at an energy selected based on the thickness of the first insulating layer and the target dopant profile.

12. The bipolar transistor of claim 11, wherein the substrate comprises at least one of a silicon substrate and a silicon-on-insulator substrate.

13. The bipolar transistor of claim 12, wherein the first insulating layer comprises a first oxide layer and the first oxide layer comprises a first portion that is grown after being deposited to increase the thickness of the first portion of the first oxide layer, and wherein the first oxide layer comprises a second portion that is not grown after being deposited.

14. The bipolar transistor of claim 13, wherein modifying the thickness of the first oxide layer comprises:
etching the first oxide layer such that the thickness of the second portion of the first oxide layer is approximately equal to a target thickness selected based upon the target dopant profile.

15. The bipolar transistor of claim 13, wherein modifying the thickness of the first oxide layer comprises:
etching the first oxide layer such that the second portion of the first oxide layer is substantially removed to expose a portion of the first layer; and
depositing a second oxide layer over at least the exposed portion of the first layer, the second oxide layer having a thickness approximately equal to a target thickness selected based upon the target dopant profile.

16. The bipolar transistor of claim 11, wherein modifying the thickness of the first insulating layer comprises modifying the thickness of the first insulating layer to correspond to a target thickness selected based on the target dopant profile.

17. The bipolar transistor of claim 16, wherein the target thickness is selected based on at least one of a target straggle of the target dopant profile, a target standard deviation of the target dopant profile, or a target depth of a peak of the target dopant profile.

18. The bipolar transistor of claim 17, wherein the target thickness is approximately 400 Å and the energy used to implant the dopant of the first type in the first oxide layer is in the range 5-30 keV for a p-type dopant.

19. The bipolar transistor of claim 17, wherein the target thickness is approximately 400 Å and the energy used to implant the dopant of the first type in the first oxide layer is in the range 50-100 keV for an n-type dopant.

20. The bipolar transistor of claim 11, wherein the first layer comprises silicon, and comprising a second layer of polysilicon formed over the first layer.
